(19) United States
(12) Patent Application Publication
(10) Pub. No.: US 2023/0155007 A1
(43) Pub. Date: May 18, 2023

(54) FIN PROFILE MODULATION

(71) Applicant: Taiwan Semiconductor Manufacturing CO., Ltd., Hsinchu (TW)

(72) Inventor: Chih-Wei CHIANG, Zhubei City (TW)

(73) Assignee: Taiwan Semiconductor Manufacturing CO., Ltd., Hsinchu (TW)

(21) Appl. No.: 17/836,628

(22) Filed: Jun. 9, 2022

Related U.S. Application Data
(60) Provisional application No. 63/279,997, filed on Nov. 16, 2021.

(51) Int. Cl. H01L 29/66; H01L 29/423; H01L 29/06; H01L 29/78; H01L 29/40; H01L 29/786

(52) U.S. Cl. CPC H01L 29/66795; H01L 29/42392; H01L 29/0669; H01L 29/7851; H01L 29/401; H01L 29/66742; H01L 29/78696

(57) ABSTRACT

Fins for use in gate all-around field effect transistors (GAAFETs) can be manufactured to have substantially uniform profiles, so the shapes of the fins are independent of size and pitch. Fin profile optimization from a tapered profile to a substantially uniform profile can be achieved via fin height control modulation using additional physical shaping operations to reduce pattern loading. These improvements in the fin profile can be accomplished by stacking and refilling a flowable chemical vapor deposition (FCVD) film multiple times and by using composition tuning during the FCVD process to further modulate fin profiles.

### RELATED APPLICATION

This application claims benefit of U.S. Provisional Patent Application No. 63/279,997, filed on Nov. 16, 2021, titled “Fin Profile Modulation,” which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is an isometric view of a FinFET, in accordance with some embodiments.

FIGS. 2A-2D are isometric views of FinFET and gate-all-around (GAA) FET structures, in accordance with some embodiments.

FIG. 3 is a flow diagram of a method for fabricating fins having tapered profiles, as shown in FIGS. 6 and 9A, in accordance with some embodiments.

FIGS. 4A-4C are cross-sectional views of nanostructured fins at various stages of their fabrication process, in accordance with some embodiments.

FIGS. 5A-5D are cross-sectional views of tapered fins at various stages of their fabrication process, in accordance with some embodiments.

FIG. 6 is a magnified cross-sectional view of a tapered fin profile, in accordance with some embodiments.

FIG. 7 is a flow diagram of a method for fabricating fins having uniform profiles, as shown in FIG. 9B, in accordance with some embodiments.

FIGS. 8A-8D are cross-sectional views of uniform fin profiles at various stages of their fabrication process, in accordance with some embodiments.

FIGS. 9A and 9B are magnified cross-sectional views of tapered and uniform fin profiles, in accordance with some embodiments.

FIGS. 10A and 10B illustrate dimensions of uniform fin profiles, in accordance with some embodiments.

FIG. 11 is a cross-sectional view of an array of substantially uniform fin profiles, in accordance with some embodiments.

FIG. 12 is a flow diagram of a method for fabricating GAAFETs, such as those shown in FIGS. 2B, 2C, and 2D, in accordance with some embodiments.

FIG. 13A-14E are cross-sectional views of GAAFETs at various stages of their fabrication process, in accordance with some embodiments.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values is typically due to slight variations in manufacturing processes or tolerances.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

The term “vertical,” as used herein, means nominally perpendicular to the surface of a substrate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Vertical structures known as “fins” can be fabricated for use in advanced transistors, such as FinFETs and gate-all-around FETs (GAAFETs) that are built on semiconductor substrates. Fins extend upward from a top surface of the substrate, allowing a transistor gate to wrap around one or more current channels of the transistor in three dimensions, thus providing improved control, reduced current leakage, and a faster switching response. Ideally, the profile of the fin top has a substantially uniform width. However, in reality, fin profiles are often tapered such that the top of the fin is narrower than the base, by as much as about 3 nm to about 5 nm. Tapered fin profiles can reduce flexibility for subsequent patterning of the transistor gate, resulting in reduced device performance. Consequences of tapered fin profiles may be worse for narrower fins than for wider fins. Thus, it is desirable to fabricate fins having a more uniform width, so the shape of the fin is independent of its size and separation distance from adjacent fins (pitch). One way to fabricate a fin having substantially vertical sidewalls is to bury the wider fin base under the surface of the substrate so that the more uniform portion of the fin protrudes from the surface. However, it is also desirable to preserve the height of the fin top while improving uniformity of the fin profile.

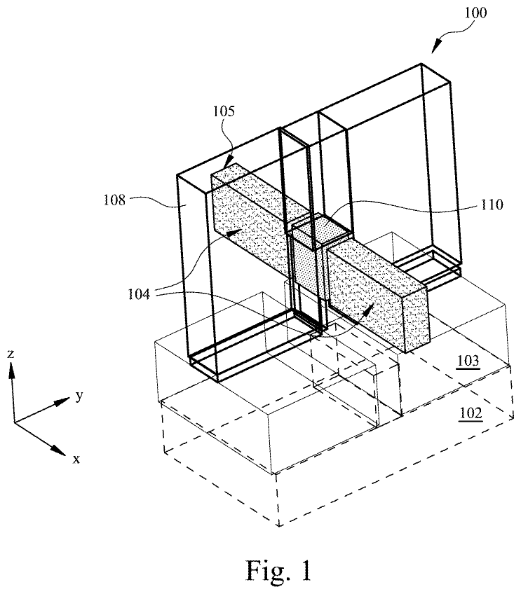

FIG. 1 is an isometric view of a FinFET 100, with transparency, in accordance with some embodiments. FinFET 100 includes a substrate 102, isolation regions 103 incorporated into substrate 102, a fin 105 having source and drain regions 104, respectively (each also referred to as “source/drain region 104”), a gate structure 108, and a channel 110.

As used herein, the term “substrate” describes a material onto which subsequent layers of material are added. The substrate itself may be patterned. Materials added on the substrate may be patterned or may remain unpatterned. Substrate 102 can be made of a semiconductor material, such as silicon (Si). Substrate 102 can be a bulk semiconductor wafer or the top semiconductor layer of a semiconductor-on-insulator (SOI) wafer (not shown), such as silicon-on-insulator. In some embodiments, substrate 102 can include a crystalline semiconductor layer with its top surface parallel to a crystal plane, e.g., one of (100), (110), (111), or c-(0001) crystal planes. In some embodiments, substrate 102 can be made from an electrically non-conductive material, such as glass, sapphire, and plastic. In some embodiments, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Substrate 102 can be doped with p-type dopants (e.g., boron (B), indium (In), aluminum (Al), or gallium (Ga)) or n-type dopants (e.g., phosphorus (P) or arsenic (As)). In some embodiments, different portions of substrate 102 can have opposite type dopants.

Shallow trench isolation (STI) regions 103 are formed in substrate 102 to electrically isolate neighboring FinFETs 100 from one another. STI regions 103 can be formed adjacent to fin 105 For example, an insulating material can be blanket deposited over and between each fin 105. The insulating material can be blanket deposited to fill trenches in substrate 102 (e.g., spaces that will be occupied by STI regions 103 in subsequent fabrication steps) surrounding fins 105. A subsequent polishing process, such as a chemical mechanical polishing (CMP) process, can substantially planarize top surfaces of STI regions 103. In some embodiments, the insulating material for STI regions 103 can include, for example, silicon oxide, silicon nitride, silicon oxynitride, fluoride-doped silicate glass (FSG), or a low-k dielectric material. In some embodiments, the insulating material for STI regions 103 can be deposited using a flowable chemical vapor deposition (FCVD) process, a high-density-plasma (HDP) CVD process, or silane (SiH₄) and oxygen (O₂) as reacting precursors. In some embodiments, the insulating material for STI regions 103 can be formed using a sub-atmospheric CVD (SACVD) process or high aspect-ratio process (HARP), where process gases can include tetraethoxysilane (TEOS) and/or ozone (O₃). In some embodiments, the insulating material for STI regions 103 can be formed using a spin-on-dielectric (SOD), such as hydrogen silsesquioxane (HSQ) and methyl silsesquioxane (MSQ).

A fin 105 including source/drain regions 104 is formed from a portion of substrate 102, extending outward from an upper surface of substrate 102 in the z-direction. Source/drain regions 104 are doped with either a positive or a negative species to provide charge reservoirs for FinFET 100. For example, for a negative FET (NFET), source/drain regions 104 can include the substrate material, such as Si, and n-type dopants. For a positive FET (PFET), source/drain regions 104 can include the substrate material, such as Si and SiGe, and p-type dopants. In some embodiments, the term “p-type” defines a structure, layer, and/or region as being doped with, for example, boron (B), indium (In), or gallium (Ga). In some embodiments, the term “n-type” defines a structure, layer, and/or region as being doped with, for example, phosphorus (P) or arsenic (As). An NFET device may be disposed in a p-type region of substrate 102, or PWELL. A PFET device may be disposed in an n-type region of substrate 102, or NWELL.

During operation of FinFET 100, current flows between source/drain regions 104, through channel 110, in response to a voltage applied to gate structure 108. Gate structure 108 surrounds three sides of the fin, so as to control the current flow through channel 110. Gate structure 108 can be a multi-layered structure that includes (not shown) a gate electrode, a gate dielectric that separates the gate electrode from the fin, and sidewall spacers. Gate structure 108 can be made of polysilicon or metal. If metal is used for gate structure 108, a temporary, or sacrificial, gate structure 108 may be formed initially from polysilicon and replaced with metal in a later operation. Gate structure 108 can be deposited, for example, by CVD, low pressure CVD (LPCVD), HDP CVD, plasma enhanced CVD (PECVD), or any other suitable deposition process. Gate structure 108 can be patterned using a photolithography process that employs a photoresist mask, a hard mask, or combinations thereof. Gate structure 108 can be etched using a dry etching process (e.g., reaction ion etching) or a wet etching process. In some embodiments, gas etchants used in the dry etching process can include chlorine, fluorine, bromine, or a combination thereof. In some embodiments, an ammonium hydroxide (NH₄OH), sodium hydroxide (NaOH), and/or potassium hydroxide (KOH) wet etch can be used to pattern gate structure 108, or a dry etch followed by a wet etch process can be used to pattern gate structure 108.

A single FinFET 100 is shown in FIG. 1. However, gate structure 108 may wrap around multiple fins 105 arranged along the y-direction to form multiple FinFETs 100. Likewise, separated regions of a single fin may be controlled by multiple gate structures 108, arranged along the x-direction, to form multiple FinFETs 100.

When a voltage applied to gate structure 108 exceeds a certain threshold voltage, FinFET 100 switches on and current flows through channel 110. When the applied voltage drops below the threshold voltage, FinFET 100 shuts off, and current ceases to flow through channel 110. Because the wrap-around arrangement of gate structure 108 influences channel 110 from three sides, improved control of the conduction properties of channel 110 is achieved in FinFET 100, compared with planar FETs, in which the gate influences current flow in the channel from a single side.

A FinFET in which channel 110 takes the form of a multi-channel stack is known as a gate-all-around (GAA) FET. In a GAAFET, the multiple channels within the stack are surrounded on all four sides by GAA gate structures, so as to further improve control of current flow in the stacked channels.

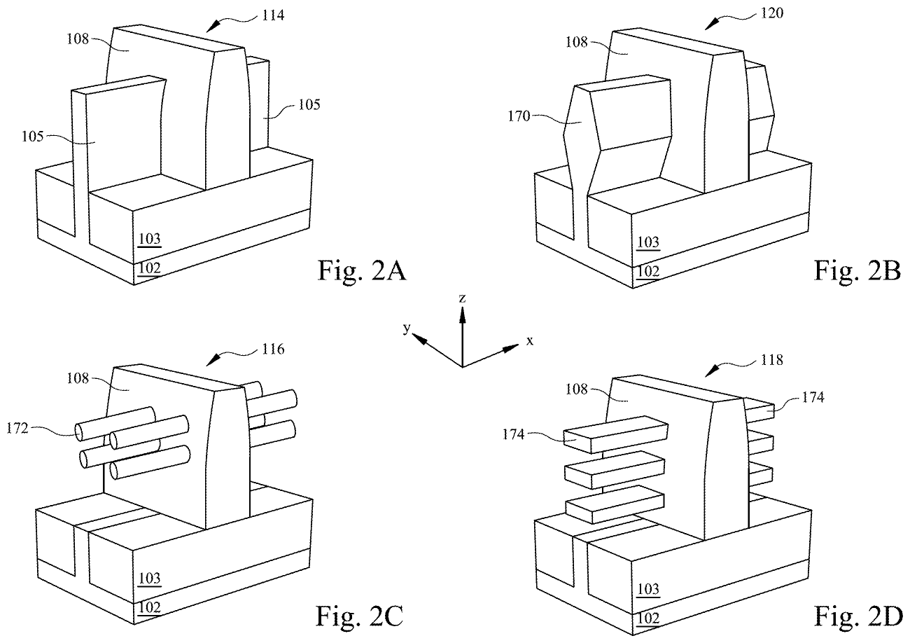

FIGS. 2A-2D illustrate different types of FinFET and GAAFET structures, in accordance with some embodiments. FIG. 2A shows an isometric view of a FinFET 114 having source/drain regions within fin 105 and a gate structure 108. FIGS. 2B-2D show similar isometric views of GAAFETs that are variations on the design of FinFET 114. GAAFETs having 1-D, linear channels, or nanowires 172 are known as nanowire FETs 116 (FIG. 2C); GAAFETs having 2-D channels, or nanosheets 174, are known as nanosheet FETs 118 (FIG. 2D). GAAFETs in which fins 105 have been recessed in the source/drain regions and replaced by epitaxial source/drain regions 170 are known as epi source/drain GAAFETs 120 (FIG. 2B). FinFETs 114 and GAAFETs 116, 118, and 120 are formed on substrate 102, in which devices are separated from one another by isolation regions 103. Structures, such as those shown in FIGS. 2A-2D, may be formed on a common substrate 102, or on different substrates.

Embodiments of the present disclosure are shown and described, by way of example, as nanosheet FETs 118 (e.g., as shown in FIG. 2D) or epi source/drain GAAFETs 120 (e.g., as shown in FIG. 2B), where the nanosheet FETs 118 and epi source/drain GAAFETs 120 feature strained channels 110. Strained channels as described herein may also be applied to other types of FETs—for example, FinFET 114 (e.g., as shown in FIG. 2A) or nanowire FETs 116 (e.g., as shown in FIG. 2C), or 2D planar FETs.

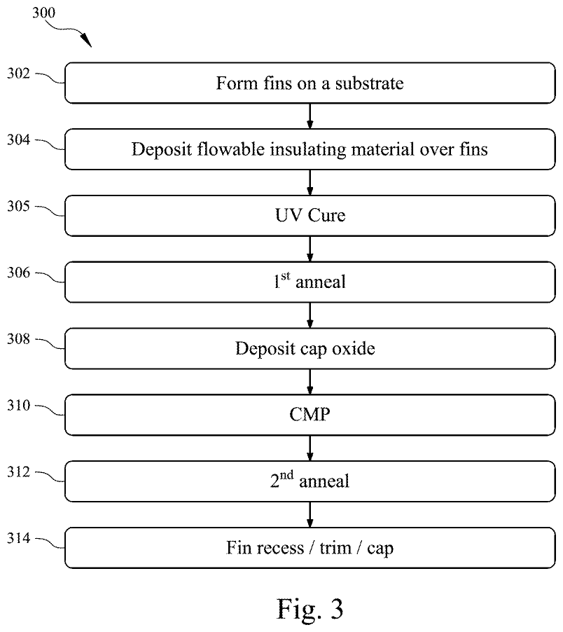

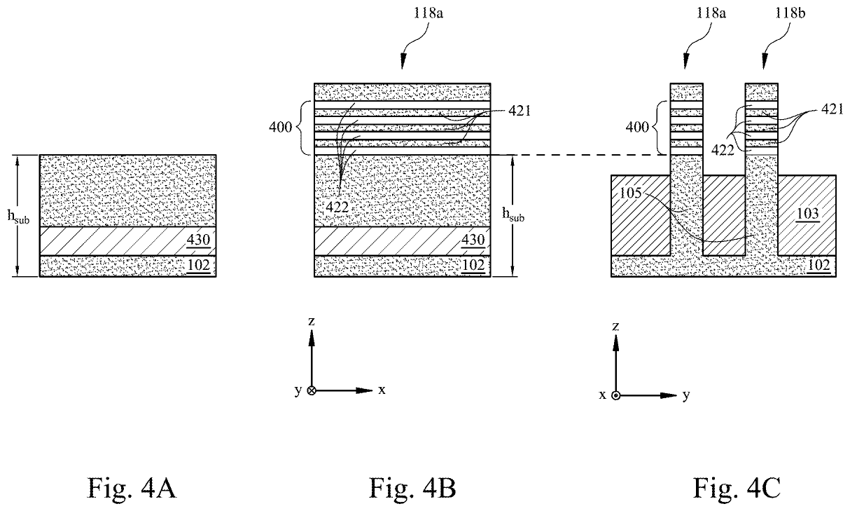

FIG. 3 is a flow diagram of a method 300 for fabricating fins 105 having either a monolithic structure for use in FinFETs 114 or nanostructured fins 105 for use in GAAFETs 116, 118, and 120, according to some embodiments. For illustrative purposes, operations illustrated in FIG. 3 will be described with reference to an exemplary process for fabricating nanostructured fins 105, as illustrated in FIGS. 4A-4C, FIGS. 5A-5E, and FIG. 6, all of which are cross-sectional views of fins at various stages of their fabrication, according to some embodiments.

Operations of method 300 can be performed in a different order, or not performed, depending on specific applications. It is noted that method 300 may not produce a complete semiconductor device, e.g., GAAFET 116, 118, or 120. Accordingly, it is understood that additional processes can be provided before, during, or after method 300, and that some of these additional processes may only be briefly described herein.

Referring to FIG. 3, in operation 302, nanostructured fins 105 are formed on substrate 102, as shown in FIGS. 4A-4C. Nanostructured fins 105 will be part of adjacent GAAFETs 118a and 118b. First, a superlattice 400 can be formed on substrate 102. FIG. 4A illustrates a cross-sectional view of substrate 102 prior to forming superlattice 400, in which substrate 102 has a total height h_{sub}. FIG. 4B illustrates a cross-sectional view of substrate 102 after formation of superlattice 400, including nanostructured channel layers 421 and nanostructured sacrificial layers 422. FIG. 4C illustrates a cross-sectional view after formation of nanostructured fins 105 and STI regions 103, where the view shown in FIG. 4C is transverse to that shown in FIG. 4B.

In some embodiments, substrate 102 may or may not take the form of a silicon-on-insulator (SOI) substrate that includes a buried layer 430 e.g., a buried SiGe layer. Buried layer 430 is shown in FIGS. 4A and 4B. In some embodiments, a layer of SiGe may be deposited or grown on substrate 102, followed by formation of a silicon layer above buried layer 430. In some embodiments, a SiGe buried layer has a composition that includes a germanium content of about 30% to about 60%. In some embodiments, SiGe buried layer 430 has a composition that includes a germanium content of about 20%. Buried layer 430 may have a thickness in a range of about 1 nm to about 30 nm.

Referring to FIGS. 4B and 4C, superlattice 400 can include a stack of nanostructured layers 421 and 422 arranged in an alternating configuration. In some embodiments, nanostructured layers 421 include materials similar to one another, e.g., epitaxial Si, and nanostructured layers 422 include materials similar to one another, e.g., epitaxial SiGe. In some embodiments, superlattice 400 are formed by etching a stack of two different semiconductor layers (not shown) arranged in the alternating configuration. Nanostructured sacrificial layers 422 are replaced in subsequent processing, while nanostructured layers 421 remain as part of semiconductor devices 118a and 118b. Although FIGS. 4B and 4C show four nanostructured layers 421 and four sacrificial nanostructured layers 122, any number of nanostructured layers can be included in each superlattice 400. The alternating configuration of superlattice 400 can be achieved by alternating deposition, or epitaxial growth, of SiGe and Si layers, starting from the top silicon layer of substrate 102. Si layers can form nanostructured layers 121, which are interleaved with SiGe nanostructured sacrificial layers 122. Each of the nanostructured layers 121-122 may have thicknesses in a range of about 1 nm to about 5 nm. In some embodiments, the topmost nanostructured layers (e.g., Si layers) of superlattice 400 may be thicker than the underlying nanostructured layers.

The stack of two different semiconductor layers can be formed via an epitaxial growth process. The epitaxial growth process can include (i) chemical vapor deposition (CVD), such as low pressure CVD (LPCVD), rapid thermal chemical vapor deposition (RTCVD), metal-organic chemical vapor deposition (MOCVD), atomic layer CVD (ALCVD), ultrahigh vacuum CVD (UHVCVD), reduced pressure CVD (RPCVD), and other suitable CVD processes; (ii) molecular beam epitaxy (MBE) processes (iii) another suitable epitaxial process; or (iv) a combination thereof. In some embodiments, source-drain regions can be grown by an epitaxial deposition/partial etch process, which repeats the epitaxial deposition/partial etch process at least once. Such repeated deposition/partial etch process is also called a “cyclic deposition-etch (CDE) process.” In some embodiments, source-drain regions can be grown by selective epitaxial growth (SEG), where an etching gas can be added to promote selective growth on exposed semiconductor surfaces of substrate 102 or fin 105, but not on insulating material (e.g., dielectric material of STI regions 103).

Superlattice 400 can be doped by introducing one or more precursors during the above-noted epitaxial growth process. For example, the stack of two different semiconductor layers can be in-situ p-type doped during the epitaxial growth process using p-type doping precursors, such as diborane (B₂H₆) and boron trifluoride (BF₃). In some embodiments, the stack of two different semiconductor layers can be in-situ n-type doped during an epitaxial growth process using n-type doping precursors, such as phosphine (PH₃) and arsine (AsH₃).

Next, superlattice 400 and underlying silicon substrate 102 can be patterned and etched to form fins 105, as shown in FIG. 4C. Top portions of fins 105 include the stacked layers e.g., Si/SiGe/Si. Bottom portions of fins 105 define trenches in substrate 102 and provide structural support for superlattice 400. The trenches around fins 105 are then filled with an insulating material to form STI regions 103, as shown in FIG. 4C.

Insulating material in STI region 103 can include, for example, silicon oxide e.g., (SiO₂), silicon nitride (SiN), silicon oxynitride (SiON), fluoride-doped silicate glass (FSG), or a low-k dielectric material, and/or other suitable insulating material. In some embodiments, STI regions 103 can include a multi-layered structure. In some embodiments, the process of depositing the insulating material can include any deposition method suitable for flowable dielectric materials (e.g., flowable silicon oxide). For example, flowable silicon oxide can be deposited for STI regions 103 using a flowable CVD (FCVD) process. The FCVD process can be followed by a wet anneal process. In some embodiments, the process of depositing the insulating material can include depositing a low-k dielectric material to form a liner. In some embodiments, a liner made of another suitable insulating material can be placed between STI region 103 and adjacent FETs.

In some embodiments, STI regions 103 may be annealed. Annealing the insulating material of STI regions 103 can include annealing the deposited insulating material in a steam environment at a temperature in a range from about 200° C. to about 700° C. for a time period in a range from about 30 min to about 120 min. The anneal process can be followed by a polishing process that can remove a surface layer of the insulating material. The polishing process can be followed by an etching process to recess the polished insulating material to form STI regions 103.

Recessing the polished insulating material can be performed, for example, by a dry etch process, a wet etch process, or a combination thereof. In some embodiments, the dry etch process for recessing the polished insulating material can include using a plasma dry etch with a gas mixture that can include octafluorocyclobutane (C₄F₈), argon (Ar), oxygen (O₂), helium (He), fluoroform (CHF₃), carbon tetrafluoride (CF₄), difluoromethane (CH₂F₂), chlorine (Cl₂), hydrogen bromide (HBr), or a combination thereof with a pressure ranging from about 1 mTorr to about 5 mTorr. In some embodiments, the wet etch process for recessing the polished insulating material can include using a diluted hydrofluoric acid (DHF) treatment, an ammonium peroxide mixture (APM), a sulfuric peroxide mixture (SPM), hot deionized water (DI water), or a combination thereof. In some embodiments, the wet etch process for recessing the polished insulating material can include using an etch process that uses ammonia (NH₃) and hydrofluoric acid (HF) as etchants and inert gases, such as Ar, xenon (Xe), He, and a combination thereof. In some embodiments, the flow rate of HF and NH₃ used in the etch process can each range from about 10 sccm to about 100 sccm (e.g., about 20 sccm, 30 sccm, or 40 sccm). In some embodiments, the etch process can be performed at a pressure ranging from about 5 mTorr to about 100 mTorr (e.g., about 20 mTorr, about 30 mTorr, or about 40 mTorr) and a temperature ranging from about 50° C. to about 120° C.

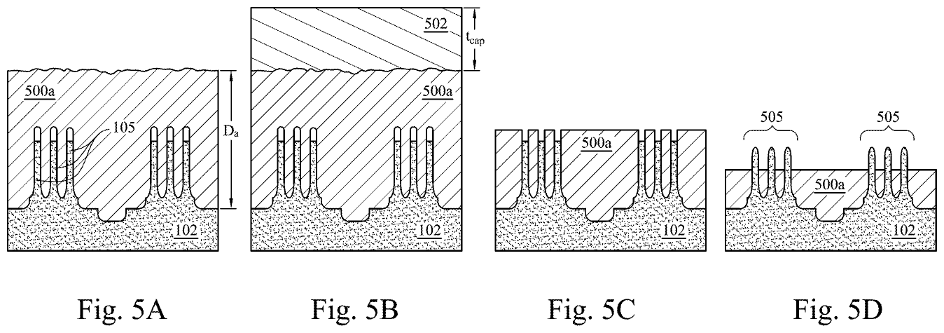

Referring to FIG. 3, in operation 304, a flowable insulating material 500a can be deposited over nanostructured fins 105 as illustrated in FIG. 5A. In some embodiments, flowable insulating material 500a has a depth Dₐ in a range of about 800 Å to about 2200 Å. In some embodiments, flowable insulating material 500a can be deposited using a flowable chemical vapor deposition (FCVD) process similar to processes that can be used to deposit STI regions 103. Flowable insulating material 500a may provide improved gap fill around high-aspect ratio fin structures, compared with blanket depositing a non-flowable insulating material. In some embodiments, flowable insulating material 500a can be deposited in a heated tube that is otherwise utilized in manufacturing glass fibers.

Referring to FIG. 3, in operation 305, flowable insulating material 500a can be cured by exposure to UV light. The curing operation can solidify and seal flowable insulating material 500a to provide structural stability, and to allow the material to withstand subsequent processing operations.

Referring to FIG. 3, in operation 306, fins 105 and flowable insulating material 500a can be annealed to densify and further strengthen flowable insulating material 500a. In some embodiments, the anneal temperature is in a range of about 500° C. to about 800° C. In some embodiments, the annealing process is performed at a temperature that is below a characteristic temperature at which flowable insulating material 500a could re-flow. For example, instead of annealing at a temperature between about 500° C. to about 800° C., a low-temperature anneal below about 400° C. can be used. Referring to FIG. 3, in operation 308, a cap oxide 502 can be deposited on top of flowable insulating material 500a, as shown in FIG. 5B. In some embodiments, cap oxide 502 can be made of silicon dioxide (SiO₂), which can be deposited using a plasma enhanced chemical vapor deposition (PECVD) process. In some embodiments, cap oxide 502 can have an as-deposited thickness trap in a range of about 1000 Å to about 2000 Å. The addition of cap oxide 502 can provide a larger window for a subsequent polishing process and can enhance depth control during the polishing operation.

Referring to FIG. 3, in operation 310, chemical mechanical planarization (CMP), also known as a polishing process, can be used to planarize the structure shown in FIG. 5B down to top surfaces of fins 105, as shown in FIG. 5C. In some embodiments, the CMP process can remove all of cap oxide 502 as well as a thickness of flowable insulating material 500a above top surfaces of fins 105, until flowable insulating material 500a is coplanar with top surfaces of fins 105.

Referring to FIG. 3, in operation 312, planarized fins 105 can be annealed a second time. In some embodiments, the second annealing process can be similar to, or the same as, the annealing process in operation 310.

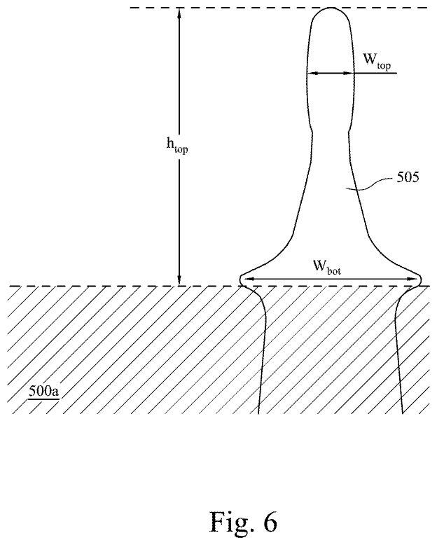

Referring to FIG. 3, in operation 314, flowable insulating material 500a can be recessed to expose top portions of fins 105, creating arrays of tapered fins 505, as shown in FIG. 5D and FIG. 6. Fin recess can be accomplished by etching flowable insulating material 500a, e.g., STI oxide, selective to fins 105, e.g., silicon or SiGe. In some embodiments, the fin recess can include removing portions of the fins 105 to adjust a taper of the tapered fins 505.

In some embodiments, operation 314 includes a plasma etching process, a wet etch process, or combinations thereof. The etching process used to recess flowable insulating material 500a may be sensitive to pattern density, which can load the etch chemistry so as to cause tapered fins 505 to have fin profiles that flare at the bottom as shown in FIG. 6. Bottom portions of tapered fins 505 may be more flared for smaller fin widths and spacings than for larger fin widths and spacings.

FIG. 6 shows a magnified view of an exemplary tapered fin 505, according to some embodiments. FIG. 6 illustrates a single tapered fin 505, indicating relevant height and width dimensions. For example, a fin top height hₜₒₚ of tapered fin 505, from the top of tapered fin 505 to the surface of flowable insulating material 500a, can be in a range of about 45 nm to about 55 nm. Near the exposed top surface of flowable insulating material 500a, a bottom width of tapered fins 505, w_{bot}, can be as much as several times wider than a top width, wₜₒₚ, of tapered fins 505. In some embodiments of tapered fins 505, w_{bo} is in a range of about 18 nm to about 22 nm. Because current flows through tapered fins 505, in FinFETs and in GAAFETs, non-uniformities in the fin profile, as well as profile variations among fins can compromise device performance of transistors 114, 116, 118, and 120.

Following fin recess, tapered fins 505 can be trimmed and a thin silicon cap (not shown) can be grown on top of tapered fins 505. Trimming lower portions of tapered fins 505 to a prescribed height can be an optional operation that is performed if needed, based on measurements of w_{bot}. In some embodiments, the silicon cap has a thickness in a range of about 1 Å to about 2 Å.

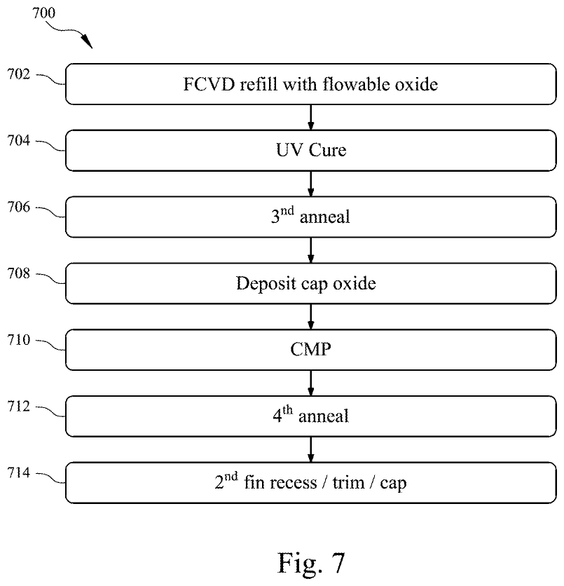

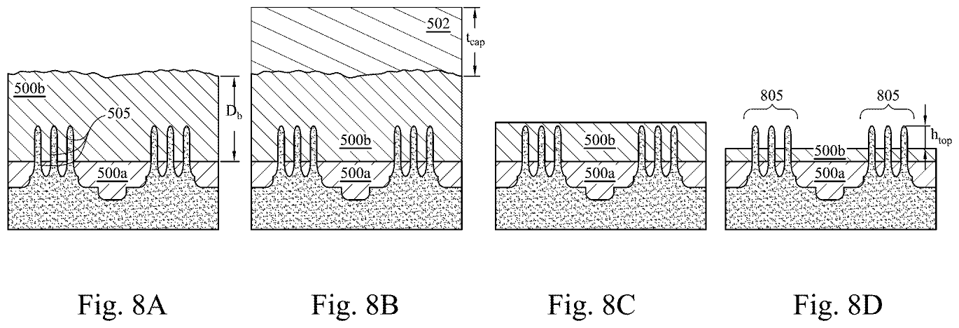

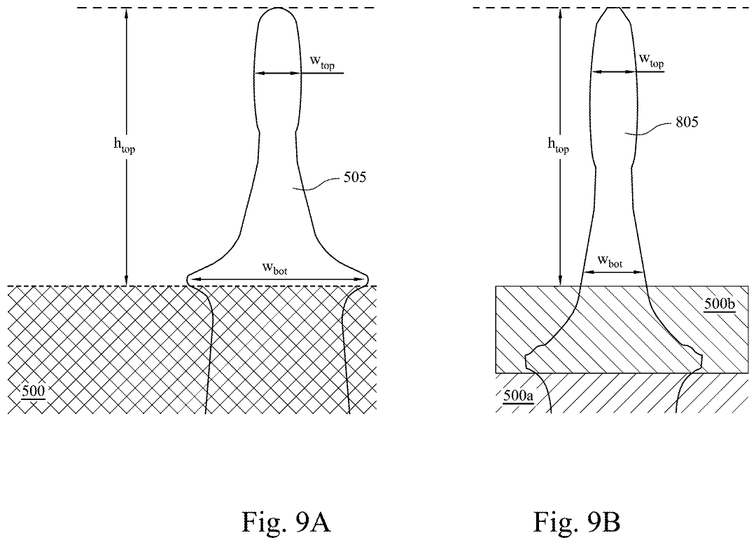

FIG. 7 is a flow diagram of a method 700 for fabricating substantially uniform fins 805 from tapered fins 505, according to some embodiments. For illustrative purposes, operations illustrated in FIG. 7 will be described with reference to the exemplary process for transforming tapered fins 505 into uniform fins 805, as illustrated in FIGS. 8A-8D and FIG. 9B, which are cross-sectional views of uniform fins 805, at various stages of their fabrication, according to some embodiments.

Operations of method 700 can be performed in a different order, or not performed, depending on specific applications. It is noted that method 700 may not produce a complete semiconductor device. Accordingly, it is understood that additional processes can be provided before, during, or after method 700, and that some of these additional processes may only be briefly described herein.

Method 700 provides fin profile optimization from a tapered profile to a substantially uniform profile throughout the top height of tapered fins 505. Method 700 also provides fin top height control modulation using extra physical shaping steps for pattern loading reduction. These improvements in the fin profile can be accomplished by stacking and refilling the FCVD film multiple times and by using composition tuning during the FCVD process, to further modulate fin profiles.

Referring to FIG. 7, in operation 702, another layer of flowable insulating material, 500b, is deposited over tapered fins 505 as shown in FIG. 8A. In some embodiments, flowable insulating material 500b has a depth D_{b} in a range of about 800 Å to about 2200 Å. In some embodiments, flowable insulating material 500b can be deposited in a heated tube that is otherwise utilized in manufacturing glass fibers. In some embodiments, flowable insulating material 500b can be deposited using a flowable chemical vapor deposition (FCVD) process similar to processes that can be used to deposit STI regions 103, and similar to the FCVD process used to deposit flowable insulating material, 500a in operation 302 of method 300. In some embodiments, the FCVD process used during operation 702 can be modified from that used during operation 302 to tune the composition of flowable insulating material 500b differently from the composition of flowable insulating material 500a. For example, the deposition of flowable insulating material 500b may occur in the presence of different gases, such as argon and oxygen, or different gas flows, than were used to deposit flowable insulating material 500a. Furthermore, gas flows used during deposition of flowable insulating material 500b around tapered fins 505 may also alter, or tune, the composition of tapered fins 505. Tuning the composition of flowable insulating material 500b and/or tapered fins 505 may produce films that respond differently to subsequent etching and polishing operations, as described below.

Referring to FIG. 7, in operation 704, flowable insulating material 500b can be cured by exposure to UV light. The curing operation can solidify and seal flowable insulating material 500b to provide structural stability, and to allow the material to withstand subsequent processing operations.

Referring to FIG. 7, in operation 706, tapered fins 505 and flowable insulating material 500a can be annealed to densify and further strengthen flowable insulating material 500a. In some embodiments, the anneal temperature is in a range of about 500° C. to about 800° C.

Referring to FIG. 7, in operation 708, a cap oxide 502 can be deposited on top of flowable insulating material 500a as shown in FIG. 8B. In some embodiments, cap oxide 502 can be made of silicon dioxide (SiO₂), which can be deposited using a plasma enhanced chemical vapor deposition (PECVD) process. In some embodiments, cap oxide 502 can have an as-deposited thickness t_{cap} in a range of about 1000 Å to about 2000 Å. The addition of cap oxide 502 can provide a larger window for a subsequent polishing process and can enhance depth control during the polishing operation.

Referring to FIG. 7, in operation 710, chemical mechanical planarization (CMP), also known as a polishing process, can be used to planarize the structure shown in FIG. 8B down to top surfaces of tapered fins 505, as shown in FIG. 8C. In some embodiments, the CMP process can remove all of cap oxide 502 as well as a thickness of flowable insulating material 500b above top surfaces of tapered fins 505, until flowable insulating material 500b is coplanar with top surfaces of tapered fins 505.

Referring to FIG. 7, in operation 712, planarized tapered fins 505 can be annealed a second time. In some embodiments, the second annealing process can be similar to, or the same as, the annealing process in operations 306, 312, and 706.

Referring to FIG. 7, in operation 714, flowable insulating material 500a can be recessed to expose top portions of uniform fins 805, as shown in FIG. 8D and FIG. 9B. The fin recess operation can be used to adjust the top height hₜₒₚ of uniform fins 805 to substantially match a top height of tapered fin 505.

Fin recess can be accomplished by etching flowable insulating material 500a, e.g., oxide, selective to uniform fins 805, e.g., silicon or SiGe. In some embodiments, operation 714 can use a plasma etching process, a wet etch process, or combinations thereof. In some embodiments, a dry etch process may utilize a gas mixture that includes, for example, octafluorocyclobutane (C₄F₈), argon (Ar), oxygen (O₂), helium (He), fluoroform (CHF₃), carbon tetrafluoride (CF₄), difluoromethane (CH₂F₂), chlorine (Cl₂), hydrogen bromide (HBr), or a combination thereof with a pressure ranging from about 1 mTorr to about 500 mTorr. In some embodiments, the wet etch process can include using a diluted hydrofluoric acid (DHF) treatment, an ammonium peroxide mixture (APM), a sulfuric peroxide mixture (SPM), hot deionized water (DI water), tetramethylammonium hydroxide (TMAH), or a combination thereof. Other gas species or chemicals suitable for the etching process are within the scope and spirit of this disclosure.

FIG. 9A reproduces FIG. 6, showing a magnified view of a tapered fin 505 for comparison with FIG. 9B, which shows a magnified view of uniform fin 805, according to some embodiments. FIG. 9B illustrates a single uniform fin 805, indicating relevant height and width dimensions. For example, a fin top height hₜₒₚ of both tapered fin 505 and uniform fin 805, from the top of fins 505 and 705 to the surface of flowable insulating material 500/500a can be in a range of about 45 nm to about 55 nm. With reference to FIG. 9B, near the exposed top surface of flowable insulating material 500a, a bottom width of uniform fin 805, w_{bot}, is approximately equal to a top width, wₜₒₚ, of uniform fin 805. In some embodiments, the width of uniform fin 805 is in a range of about 3 nm to about 8 nm. FIG. 9B shows that the additional FCVD refill operation 702 has effectively buried the widest lower portion of the fin and retained the uniform upper portion as fin 805.

Referring still to FIG. 7, in operation 714 and following the fin recess, uniform fins 805 can be trimmed and a silicon cap (not shown) can be grown on top of uniform fins 805. Trimming lower portions of uniform fin 805 can be an optional operation that is done if needed, based on measurements of w_{bot}. In some embodiments, the silicon cap has a thickness in a range of about 1 Å to about 2 Å.

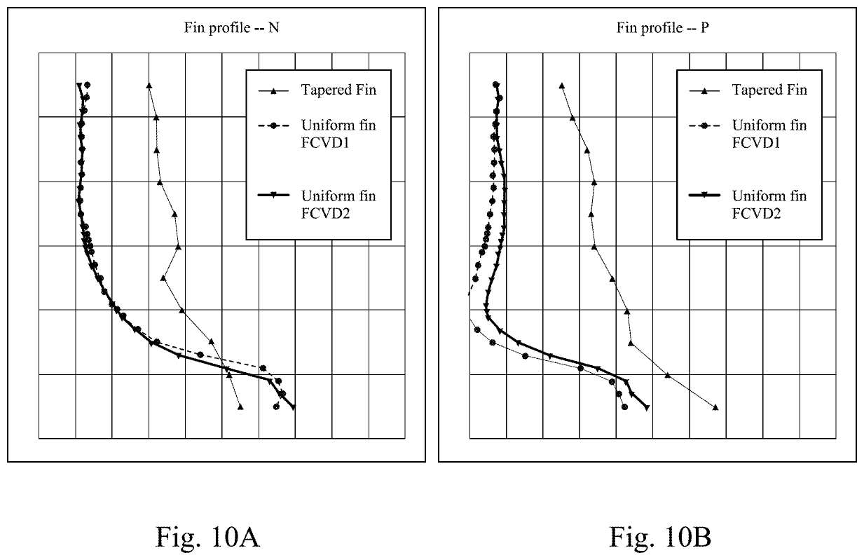

FIGS. 10A and 10B show variations in NMOS and PMOS fin profiles, respectively, according to some embodiments. The rightmost profiles correspond to tapered fin 505. The leftmost fin profiles correspond to substantially uniform fins 805, for different deposition process parameters used in FCVD refill operation 702. In some embodiments, first and second sets of process conditions “FCVD1” and “FCVD2,” respectively, can correspond to different gas chemistries used during flowable CVD deposition, e.g., different amounts of oxygen (O₂) flow, and argon (Ar) flow that can be present during deposition to tune the composition of uniform fins 805. In some embodiments, first and second sets of process conditions “FCVD1” and “FCVD2,” respectively, can correspond to different ultraviolet (UV) light conditions used in post-FCVD UV cure operation 704. Variations in process conditions used during operations 702 and 704 may be combined to further shape fin profiles to achieve substantially vertical fin profiles having a substantially uniform width along the exposed top height of uniform fins 805.

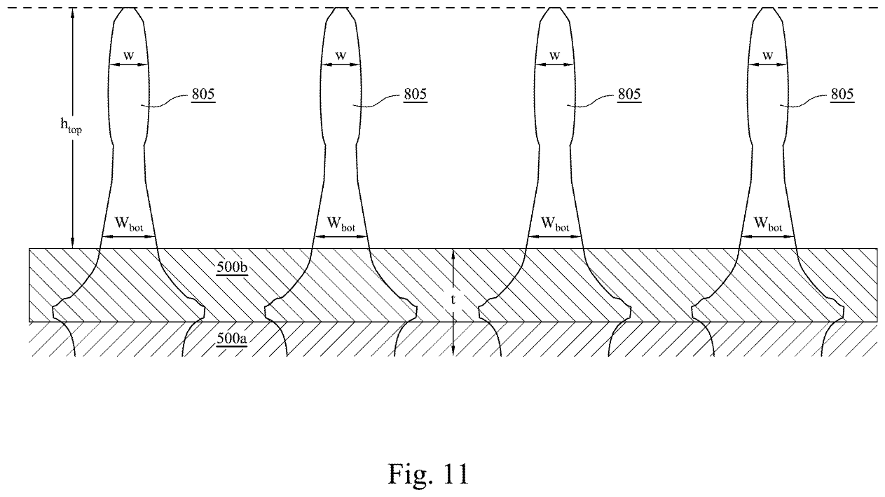

FIG. 11 shows an array of substantially uniform fins 805, following two iterations of method 700, according to some embodiments. FIG. 11 shows that a first FCVD refill operation 702 has been performed to deposit flowable insulating material 500a. In addition, FIG. 11 shows that a second FCVD refill operation 702 has also been performed to deposit flowable insulating material 500b, after repeating operations 704-714 of method 700, including curing, annealing, polishing, recessing trimming, and capping uniform fins 805. Following two iterations of method 700, a final thickness t of flowable insulating material between uniform fins 805, including flowable insulating materials 500a and 500b can be in a range of about 500 Å to about 4000 Å. The final thickness t will be substantially the same as the remaining thickness of 500a in FIG. 5D. In some embodiments, method 700 can be repeated any number of times, thus stacking multiple layers of flowable insulating material among tapered fins 505, to further modulate profiles of uniform fins 805.

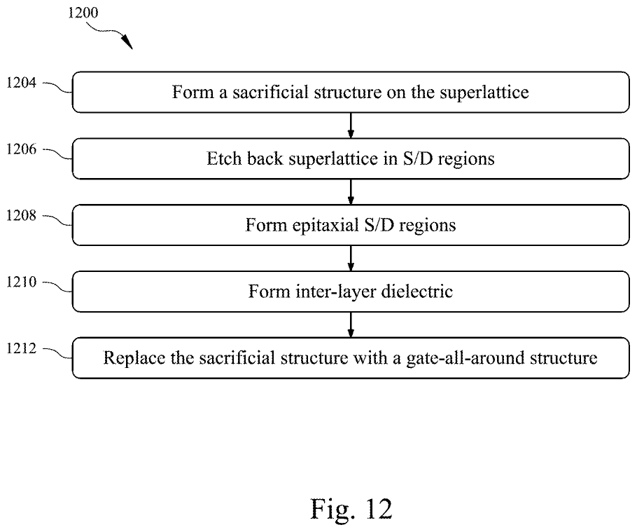

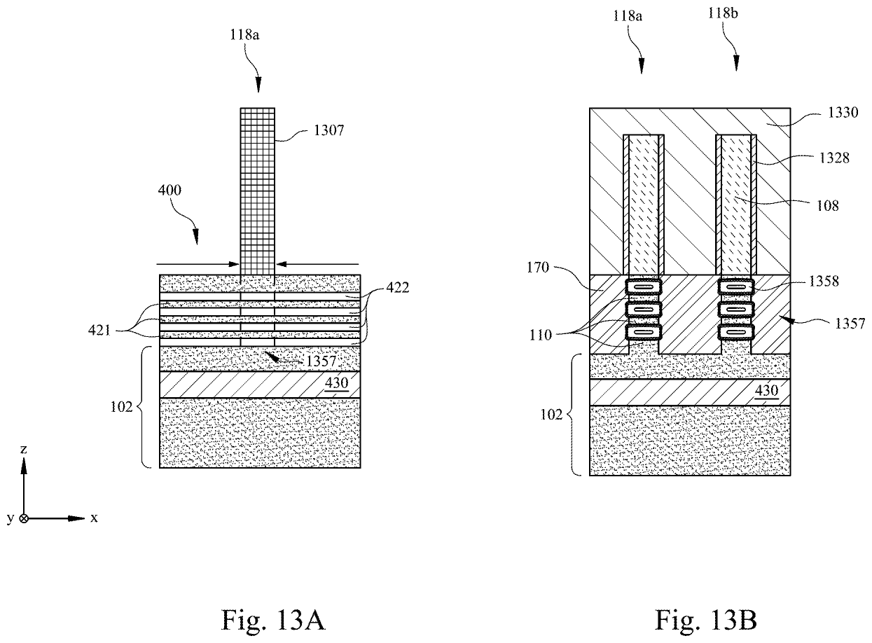

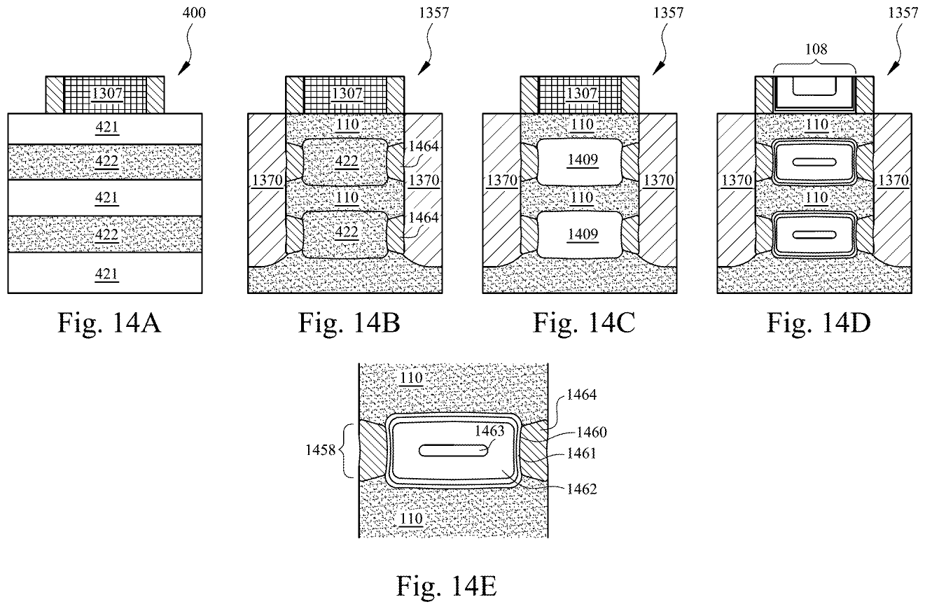

FIG. 12 is a flow diagram of a method 1200 for fabricating nanosheet GAAFETs 118 and 120 from nanostructured uniform fins 805, according to some embodiments. For illustrative purposes, operations illustrated in FIG. 12 will be described with reference to the exemplary process as illustrated in FIGS. 13A-13B and FIGS. 14A-14E, which are cross-sectional views of GAAFETs 120 at various stages of their fabrication, according to some embodiments.

Operations of method 1200 can be performed in a different order, or not performed, depending on specific applications. It is noted that method 1200 may not produce a complete semiconductor device, e.g., GAAFET 116, 118, or 120. Accordingly, it is understood that additional processes can be provided before, during, or after method 1200, and that some of these additional processes may only be briefly described herein.

Referring again to FIG. 12, following formation of superlattice 400, in operation 1204, a sacrificial gate structure 1307 can be formed on superlattice 400, as shown in FIG. 13A. Sacrificial gate structure 107 can later be replaced by a metal gate structure 108 having sidewall spacers 1328 as shown in FIG. 13B. Sacrificial gate structure 1307 can be deposited and then patterned using a hard mask, e.g., an oxide material that can be grown and/or deposited using an ALD process. When sacrificial gate structure 1307 is replaced by a metal gate 108, gate-all-around (GAA) structures 1358 will also replace sacrificial layers 422 in gate region 1357.

Still referring to FIG. 12, in operation 1204, gate spacers 1328 can be formed on sacrificial gate structure 1307. The process of forming gate spacers 1328 can include conformally depositing a spacer material layer to cover sidewalls of polysilicon sacrificial gate structure 1307, superlattice 400, and STI regions 103. In some embodiments, the spacer material layer can include (i) a dielectric material, such as silicon oxide, silicon carbide, silicon nitride, and silicon oxy-nitride, (ii) an oxide material, (iii) a nitride material, (iv) a low-k material, or (v) a combination thereof. The process of forming gate spacers 1328 can further include patterning processes e.g., lithography and etching processes. In some embodiments, the etching process can be an anisotropic etch that removes the spacer material layer faster on horizontal surfaces (e.g., on the X-Y plane) compared to vertical surfaces (e.g., on the Y-Z or X-Z planes). In some embodiments, the gate spacers 1328 can have a thickness in a range of about 1 nm to about 8 nm.

Referring to FIG. 12, in operation 1206, superlattice 400, which makes up uniform fins 805, can be etched back in source/drain regions, as shown by the dashed lines and arrows in FIG. 13A. The etch-back operation can use any suitable etching process described above. Following the etch-back operation, layers of superlattice 400 remain in a channel region 1357 underneath sacrificial gate structure 1307 as shown in FIG. 13B.

Referring to FIG. 12, in operation 1208, epitaxial source/drain regions 170 can be formed, as shown in FIG. 13B. In some embodiments, epitaxial source/drain regions 170 made of silicon or SiGe are grown from nanostructured layers 421 and/or 422 of superlattice 400 underneath sacrificial gate structure 1307. Epitaxial source/drain regions 170 can have elongated hexagonal-shaped cross-sections as shown in FIG. 2B. Epitaxial source/drain regions 170 can be formed in similar fashion as other epitaxial layers described above.

Referring to FIG. 12, in operation 1210, an inter-layer dielectric (ILD) 1330 can be formed, as shown in FIG. 13B, through which electrical contacts can be made to source, drain, and gate terminals of nanosheet FETs 118a and 118b. ILD 1330 may include silicon dioxide or a low-k dielectric material, such as a fluorosilicate glass, a carbon-doped silicon dioxide, a porous silicon dioxide, a porous carbon-doped silicon dioxide, a hydrogen silsesquioxane, a methylsilsesquioxane, a polyimide, a polynorbornene, a benzocyclobutene, and a polytetrafluoroethylene. For forming ILD 1330, a deposition process, such as chemical vapor deposition, plasma-enhanced chemical vapor deposition, and spin coating, may be performed.

Referring to FIG. 12, in operation 1212, sacrificial structure 1307 can be removed and replaced with a metal gate 108 and gate-all-around structures 1358, as shown in FIGS. 13B and 14B-14E. In operation 1212, nanostructured layers 422 are selectively removed to form gate openings 1409 in the channel region. Gate openings 1409 are then filled with metal by depositing gate structure 108, to complete GAA channel region 1357, as shown in FIG. 14D. Remaining nanostructured channel layers 421 of superlattice 400 form nanostructured channels 110 of nanosheet FETs 118a and 118b. Each of GAA channel regions 1357 can include GAA structures 1358 (two shown in FIG. 14C).

FIGS. 14A-14E are magnified views showing operations for forming gate structure 108 and GAA channel region 1357, shown in FIG. 14C, according to some embodiments. GAA channel region 1357 includes multiple GAA structures 1358, which surround channels 110 to control current flow therein. Each GAA structure 1358 can be viewed as a radial gate stack that includes, from the outermost layer to the innermost layer, a gate dielectric layer 1461, a work function metal layer 1462, and a gate electrode 1463. Gate electrode 1463 is operable to maintain a capacitive applied voltage across nanostructured channels 110. Gate dielectric layer 1461 separates the metallic layers of GAA structure 1358 from nanostructured channels 110. Inner spacers 1464 electrically isolate GAA structure 1358 from epitaxial source/drain region 1470 and prevent current from leaking out of nanostructured channels 110.

FIG. 14A is a magnified cross-sectional view of superlattice 400 and sacrificial structure 1307 shown in FIG. 4C. When superlattice 400 is etched back, a remaining portion of superlattice 400 is in GAA channel region 1357, underneath sacrificial structure 1307. Inner spacers 1464 are then formed adjacent to nanostructured layers 422 in the GAA channel region 1357.

FIG. 14B is a magnified cross-sectional view of nanosheet FETs 118. FIG. 4B illustrates GAA channel region 1357 following formation of inner spacers 1464 and epitaxial source/drain regions 170 which can be grown laterally outward, in the x-direction, from nanostructured layers 121.

FIG. 14C shows GAA channel region 1357, following extraction of nanostructured layers 422 and thus forming gate openings 1409.

FIG. 14D is a magnified view of GAA channel region 1357, shown in FIG. 13B, following replacement of sacrificial structure 1307 with gate structure 108. First, sacrificial structure 1307 is removed, leaving sidewall spacers 1328 in place. Then, gate structure 108 is grown in a multi-step process to form a metal gate stack in place of sacrificial structure 1307. Simultaneously, the radial gate stack is formed to fill gate openings 1409 from the outside in, starting with gate dielectric layer 1461, and ending with gate electrode 1463.

Referring to FIG. 14E, gate dielectric layer 1461 can have a thickness between about 1 nm and about 5 nm. Gate dielectric layer 1461 can include a silicon oxide and may be formed by CVD, atomic layer deposition (ALD), physical vapor deposition (PVD), e-beam evaporation, or another suitable deposition process. In some embodiments, gate dielectric layer 1461 includes a high-k material, where the term “high-k” refers to a high dielectric constant. In the field of semiconductor device structures and manufacturing processes, high-k refers to a dielectric constant that is greater than the dielectric constant of SiO₂ (e.g., greater than 3.9). In some embodiments, the dielectric layer can include a silicon oxide, silicon nitride, and/or silicon oxynitride material, or a high-k dielectric material, such as hafnium oxide (HfO₂). A high-k gate dielectric may be formed by ALD and/or other deposition methods. In some embodiments, the gate dielectric layer can include a single layer or multiple insulating material layers.

Gate work function metal layer 1462 can include a single metal layer or a stack of metal layers. The stack of metal layers can include metals having work functions similar to or different from each other. In some embodiments, the gate work function metal layer can include, for example, aluminum (Al), copper (Cu), tungsten (W), titanium (Ti), tantalum (Ta), cobalt (Co), metal nitrides, metal silicides, metal alloys, and/or combinations thereof. The gate work function metal layer can be formed using a suitable process, such as ALD, CVD, PVD, plating, and combinations thereof. In some embodiments, the gate work function metal layer can have a thickness in a range of about 2 nm to about 15 nm.

Gate electrode 1463 may further include a gate metal fill layer. The gate metal fill layer can include a single metal layer or a stack of metal layers. The stack of metal layers can include metals different from each other. In some embodiments, the gate metal fill layer can include one or more suitable conductive materials or alloys, such as Ti, Al, TiN, and the like. The gate metal fill layer can be formed by ALD, PVD, CVD, or other suitable deposition processes. Other materials, dimensions, and formation methods for the gate dielectric layer 161, the gate work function metal layer 1462, and the gate electrode 1463 are within the scope and spirit of this disclosure.

Following formation of gate structures 108 and GAA structures 1358 in GAA channel regions 1357, the structures of nanosheet FETs 118a and 118b, which include uniform fins 805, are substantially complete, as shown in the isometric view of FIG. 2B and the cross-sectional view of FIG. 13B.

In some embodiments, a method includes: forming fins on a substrate; forming an insulating material between the fins; depositing a oxide over the insulating material to refill a space between the fins; exposing the fins to a first annealing process; planarizing the oxide; exposing the fins to a second annealing process; and recessing the fins to expose top portions of the fins.

In some embodiments, a method includes: forming, on an isolation region, fins with each fin having a base portion and a top portion narrower than the base portion; depositing a refill material to cover the base portions of the fins to form substantially uniform fins having substantially vertical sidewalls; curing the refill material; annealing the fins; and recessing a portion of the refill material to adjust a height of the fins.

In some embodiments, a structure includes: a semiconductor substrate; an insulating material in the semiconductor substrate; and an array of fins extending out from a surface of the semiconductor substrate, where adjacent fins of the array of fins are separated by the insulating material, and where the array of fins has substantially equal fin widths and substantially equal fin heights.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A method, comprising:
forming fins on a substrate;
forming an insulating material between the fins;
depositing an oxide over the insulating material to refill a space between the fins;
exposing the fins to a first annealing process;
planarizing the oxide;
exposing the fins to a second annealing process; and
recessing the fins to expose top portions of the fins.

2. The method of claim 1, wherein depositing the oxide comprises exposing the fins to one or more of oxygen gas and argon gas to tune a composition of the exposed fins.

3. The method of claim 1, wherein the oxide is a flowable oxide, and further comprising exposing the flowable oxide to ultraviolet light.

4. The method of claim 1, wherein exposing the fins to the first and second annealing processes comprises heating the fins to a temperature in a range of about 500° C. to about 800° C.

5. The method of claim 1, wherein planarizing the oxide comprises:
depositing a cap oxide over the insulating material; and
polishing the cap oxide and the insulating material to be coplanar with a top surface of the fins.

6. The method of claim 1, wherein recessing the fins comprises:
trimming the fins to a predetermined height; and
capping the trimmed fins with silicon.

7. The method of claim 6, wherein trimming the fins comprises trimming the fins to a height in a range of about 45 nm to about 60 nm.

8. The method of claim 1, wherein recessing the fins comprises removing portions of the insulating material and portions of the fins.

9. A method comprising:
forming, on an isolation region, fins with each fin having a base portion and a top portion narrower than the base portion;
depositing a refill material to cover the base portions of the fins to form substantially uniform fins having substantially vertical sidewalls;
curing the refill material;
annealing the fins; and
recessing a portion of the refill material to adjust a height of the fins.

10. The method of claim 9, wherein forming the fins comprises forming a nanostructured stack of alternating layers.

11. The method of claim 10, wherein forming the nanostructured stack of alternating layers comprises forming epitaxial silicon layers alternating with epitaxial SiGe layers.

12. The method of claim 10, wherein forming the fins further comprises:
patterning the nanostructured stack of alternating layers; and
depositing a flowable shallow trench isolation (STI) material to insulate the nanostructured stack of alternating layers from neighboring devices.

13. The method of claim 9, wherein depositing the refill material comprises depositing a flowable oxide using a flowable chemical vapor deposition (FCVD) process.

14. The method of claim 9, wherein annealing the fins comprises annealing the fins at a temperature lower than a reflow temperature of the refill material.

15. A structure, comprising:
a semiconductor substrate;
an insulating material in the semiconductor substrate; and
an array of fins extending out from a surface of the semiconductor substrate, wherein adjacent fins of the array of fins are separated by the insulating material,
the insulating material between the fins covers a widest portion of each fin in the array of fins, and
the array of fins has substantially equal fin widths and substantially equal fin heights.

16. The structure of claim 15, wherein the substantially equal fin widths are in a range of about 3 nm to about 8 nm.

17. The structure of claim 15, wherein the substantially equal fin heights are in a range of about 45 nm to about 60 nm.

18. The structure of claim 15, further comprising a silicon cap on top of each fin in the array of fins.

19. The structure of claim 18, wherein the silicon cap has a thickness in a range of about 1 Å to about 2 Å.

20. The structure of claim 15, wherein a thickness of insulating material between the fins is in a range of about 500 Å to about 4000 Å.
